(19) United States
(12) Patent Application Publication
(10) Pub. No.: US 2025/0331321 A1
(43) Pub. Date: Oct. 23, 2025

(54) PHOTODETECTION DEVICE

(71) Applicant: SUMITOMO ELECTRIC INDUSTRIES, LTD., Osaka (JP)

(72) Inventors: Balasekaran SUNDARARAJAN, Osaka-shi (JP); Masaki MIGITA, Osaka-shi (JP); Hiroshi INADA, Osaka-shi (JP)

(73) Assignee: SUMITOMO ELECTRIC INDUSTRIES, LTD., Osaka (JP)

(21) Appl. No.: 19/185,928

(22) Filed: Apr. 22, 2025

(30) Foreign Application Priority Data
Apr. 23, 2024 (JP) 2024-070010

(51) Int. Cl. H10F 39/18; H10F 39/00

(52) U.S. Cl. CPC H10F 39/184; H10F 39/804

(57) ABSTRACT

A photodetection device includes a sensor array including a compound semiconductor substrate including a first main surface and a second main surface located opposite to the first main surface, and a plurality of light-receiving elements arranged in a two dimensional manner on the first main surface, a readout circuit including a silicon substrate having a third main surface connected to the first main surface of the compound semiconductor substrate and a fourth main surface located opposite to the third main surface, an adhesive layer provided on the fourth main surface, and a ceramic substrate connected to the fourth main surface of the silicon substrate with the adhesive layer. The silicon substrate has a thickness smaller than a thickness of the compound semiconductor substrate.

### CROSS REFERENCE TO RELATED APPLICATIONS

This application claims priority based on Japanese Patent Application No. 2024-070010 filed on Apr. 23, 2024, and the entire contents of the Japanese patent application are incorporated herein by reference.

### TECHNICAL FIELD

The present disclosure relates to a photodetection device.

### BACKGROUND

Patent literature (Japanese Unexamined Patent Application Publication No. 2021-34644) discloses a light detecting apparatus in which a two-dimensional-array light-receiving element and a readout circuit are connected via In bumps.

### SUMMARY

A photodetection device according to an aspect of the present disclosure includes a sensor array including a compound semiconductor substrate including a first main surface and a second main surface located opposite to the first main surface, and a plurality of light-receiving elements arranged in a two dimensional manner on the first main surface, a readout circuit including a silicon substrate having a third main surface connected to the first main surface of the compound semiconductor substrate and a fourth main surface located opposite to the third main surface, an adhesive layer provided on the fourth main surface, and a ceramic substrate connected to the fourth main surface of the silicon substrate with the adhesive layer. The silicon substrate has a thickness smaller than a thickness of the compound semiconductor substrate.

### BRIEF DESCRIPTION OF THE DRAWINGS

FIG. 1 is a plan view schematically illustrating a photodetection device according to an embodiment.

FIG. 2 is a cross-sectional view taken along line II-II of FIG. 1.

FIG. 3 is an enlarged view of a part of FIG. 2.

### DETAILED DESCRIPTION

The two-dimensional-array light-receiving element includes a compound semiconductor substrate. The readout circuit includes a silicon substrate. The compound semiconductor substrate and the silicon substrate may warp due to a temperature change caused by a difference between a thermal expansion coefficient of a compound semiconductor and a thermal expansion coefficient of silicon. Since the thermal expansion coefficient of the compound semiconductor is larger than the thermal expansion coefficient of silicon, when the photodetection device is cooled, for example, an amount of shrinkage of the compound semiconductor substrate is larger than an amount of shrinkage of the silicon substrate. As a result, the compound semiconductor substrate and the silicon substrate are warped. When an amount of warpage increases, cracks may be generated in the compound semiconductor substrate or the silicon substrate. In general, a thickness of the compound semiconductor substrate is set to be smaller than a thickness of the silicon substrate in consideration of the difference in thermal expansion coefficient.

The present disclosure provides a photodetection device having a new structure.

### DESCRIPTION OF EMBODIMENTS OF PRESENT DISCLOSURE

First, embodiments of the present disclosure will be listed and described.
(1) A photodetection device includes a sensor array including a compound semiconductor substrate including a first main surface and a second main surface located opposite to the first main surface, and a plurality of light-receiving elements arranged in a two dimensional manner on the first main surface, a readout circuit including a silicon substrate having a third main surface connected to the first main surface of the compound semiconductor substrate and a fourth main surface located opposite to the third main surface, an adhesive layer provided on the fourth main surface, and a ceramic substrate connected to the fourth main surface of the silicon substrate with the adhesive layer. The silicon substrate has a thickness smaller than a thickness of the compound semiconductor substrate.

The photodetection device of the embodiment has a new structure in which the silicon substrate has a thickness smaller than a thickness of the compound semiconductor substrate.
(2) In the above (1), the sensor array may include an insulating film provided on the second main surface. The insulating film may have a thickness of 0.5 μm or less.
(3) In the above (1) or (2), the first main surface may have an area of 3 cm² or more.
(4) In any one of the above (1) to (3), the adhesive layer may include a silicone resin.
(5) In any one of the above (1) to (4), the compound semiconductor substrate may have a thickness of 250 μm to 350 μm.
(6) In any one of the above (1) to (5), the silicon substrate may have a thickness of 150 μm to 250 μm.

### DETAILS OF EMBODIMENTS OF PRESENT DISCLOSURE

Hereinafter, embodiments of the present disclosure will be described in detail with reference to the accompanying drawings. In the description of the drawings, the same or equivalent elements are denoted by the same reference numerals, and redundant description thereof will be omitted. In the drawings, an X-axis direction, a Y-axis direction, and a Z-axis direction intersecting with each other are shown. The X-axis direction, the Y-axis direction, and the Z-axis direction are orthogonal to each other, for example.

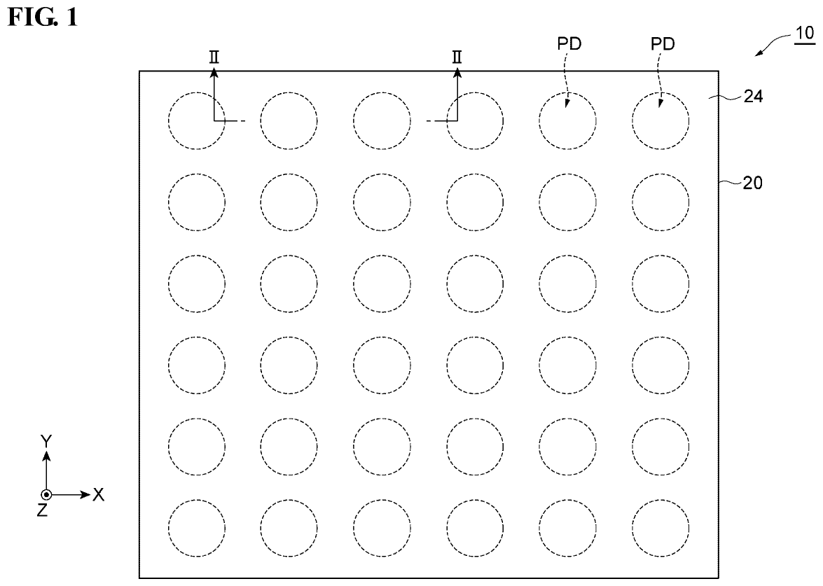

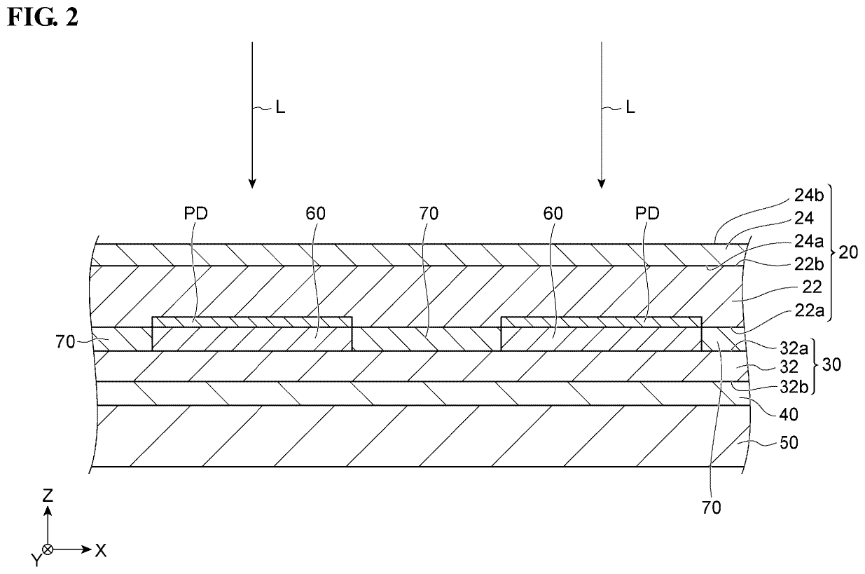

FIG. 1 is a plan view schematically illustrating a photodetection device according to an embodiment. FIG. 2 is a cross-sectional view taken along line II-II of FIG. 1. As shown in FIG. 1 and FIG. 2, a photodetection device 10 includes a sensor array 20, a readout circuit (Read Out Integrated Circuit: ROIC) 30, an adhesive layer 40, and a ceramic substrate 50. Photodetection device 10 may be an image sensor capable of detecting a light L. Light L may be light having a wavelength of 4 μm to 15 μm.

Sensor array 20 may include a compound semiconductor substrate 22, a plurality of light-receiving elements PD, and an insulating film 24. Sensor array 20 does not have to include insulating film 24. Compound semiconductor substrate 22 includes a first main surface 22a and a second main surface 22b opposite to first main surface 22a. Second main surface 22b is an incident surface on which light L is incident. Each of first main surface 22a and second main surface 22b may have a rectangular shape. An area of each of first main surface 22a and second main surface 22b may be 3 cm² or more, or may be 4 cm² or more.

Compound semiconductor substrate 22 may include a compound semiconductor such as a III-V compound semiconductor. An example of the III-V compound semiconductor includes gallium antimonide (GaSb). The compound semiconductor included in compound semiconductor substrate 22 may have a Young's modulus smaller than a Young's modulus of silicon. A Young's modulus of GaSb is 63.1 GPa. The Young's modulus of silicon is 163 GPa. Compound semiconductor substrate 22 may have a thickness of 200 μm to 500 μm. Compound semiconductor substrate 22 may have a thickness of 250 μm to 400 μm. Compound semiconductor substrate 22 may have a thickness of 350 μm or less. Compound semiconductor substrate 22 may have a thickness of 600 μm or less. In the embodiment, compound semiconductor substrate 22 has a thickness of 300 μm.

The plurality of light-receiving elements PD are arranged on first main surface 22a. As shown in FIG. 1, the plurality of light-receiving elements PD may be arranged in a two dimensional manner on first main surface 22a. Each of light-receiving elements PD may be a photodiode.

Insulating film 24 is provided on second main surface 22b of compound semiconductor substrate 22. Insulating film 24 may be provided over entire second main surface 22b. Insulating film 24 may be formed by plasma chemical vapor deposition (CVD). Insulating film 24 may have a transmittance of 90% or more with respect to light L.

Insulating film 24 includes an insulating material. A thermal expansion coefficient of the insulating material included in insulating film 24 may be smaller than a thermal expansion coefficient of the compound semiconductor included in compound semiconductor substrate 22. The thermal expansion coefficient of the insulating material included in insulating film 24 may be more than 2.5×10⁻⁶ [/K] and 5×10⁻⁶ [/K] or less. Examples of the insulating material included in insulating film 24 include silicon nitrides (SiNₓ), silicon oxides (SiO₂), and silicon oxynitrides (SiOₓN_{y}). A thermal expansion coefficient of SiNₓ is 2.9×10⁻⁶ [/K].

The insulating material included in insulating film 24 may have a Young's modulus larger than the Young's modulus of the compound semiconductor included in compound semiconductor substrate 22. A Young's module of SiNₓ is 97 GPa to 168 GPa. A Young's module of SiOₓN_{y} is 67 GPa to 94 GPa. The Young's modulus of SiNₓ or SiOₓN_{y} can be adjusted by a flow rate of silane gas when insulating film 24 is formed.

Insulating film 24 may have a thickness of 0.5 μm or less. In the embodiment, insulating film 24 has a thickness of 0.3 μm. Insulating film 24 includes a lower surface 24a located on second main surface 22b and an upper surface 24b located opposite to lower surface 24a. In the embodiment, the thickness of insulating film 24 is substantially the same over the entire insulating film 24. That is, in the embodiment, lower surface 24a and upper surface 24b are parallel to each other, and each of lower surface 24a and upper surface 24b is flat. Here, “the thickness of insulating film 24 is substantially the same” is not limited to the case where insulating film 24 has the same thickness in all the locations. Even if a slight difference, a manufacturing error, or a measurement error within a predetermined range is included, the thickness of insulating film 24 may be regarded as substantially the same.

Readout circuit 30 receives an electric signal from sensor array 20. Readout circuit 30 may include a multiplexer with a complementary metal oxide semiconductor (CMOS). Readout circuit 30 includes a silicon substrate 32. Silicon substrate 32 includes a third main surface 32a connected to first main surface 22a of compound semiconductor substrate 22 and a fourth main surface 32b opposite to third main surface 32a. Third main surface 32a includes a circuit. Each of third main surface 32a and fourth main surface 32b may have a rectangular shape. An area of each of third main surface 32a and fourth main surface 32b may be 4 cm² or more, or may be 4.5 cm² or more. The area of each of third main surface 32a and fourth main surface 32b may be larger than the area of each of first main surface 22a and second main surface 22b, or may be smaller than the area of each of first main surface 22a and second main surface 22b.

Silicon substrate 32 may have a thickness of 150 μm to 400 μm. Silicon substrate 32 may have a thickness of 200 μm to 300 μm. Silicon substrate 32 may have a thickness of 250 μm or less. In the embodiment, silicon substrate 32 has a thickness of 200 μm. A thermal expansion coefficient of silicon included in silicon substrate 32 may be smaller than the thermal expansion coefficient of the compound semiconductor included in compound semiconductor substrate 22. The thermal expansion coefficient of silicon is 1.6×10⁻⁶ [/K]. As described above, an example of the III-V compound semiconductor included in compound semiconductor substrate 22 includes GaSb, and a thermal expansion coefficient of GaSb is 5.4×10⁻⁶ [/K].

Adhesive layer 40 is provided on fourth main surface 32b of silicon substrate 32. Adhesive layer 40 may include at least one of a silicone resin or a cured silver paste. In the embodiment, adhesive layer 40 includes a silicone resin. Adhesive layer 40 may have a thickness of 100 μm to 400 μm. In the embodiment, adhesive layer 40 has a thickness of 300 μm.

Ceramic substrate 50 is connected to fourth main surface 32b of silicon substrate 32 with adhesive layer 40. That is, in photodetection device 10, adhesive layer 40 is arranged between fourth main surface 32b and ceramic substrate 50. Ceramic substrate 50 may include aluminum nitride (AlN). Ceramic substrate 50 may have a thickness larger than a thickness of compound semiconductor substrate 22. Ceramic substrate 50 may have a thickness of 600 μm to 900 μm. In the embodiment, ceramic substrate 50 has a thickness of 750 μm. A thermal expansion coefficient of a ceramic material included in ceramic substrate 50 may be smaller than the thermal expansion coefficient of the compound semiconductor included in compound semiconductor substrate 22. The thermal expansion coefficient of the ceramic material included in ceramic substrate 50 may be larger than the thermal expansion coefficient of silicon. A thermal expansion coefficient of AlN is 2.8×10⁻⁶ [/K].

Here, the relationship between the thicknesses of compound semiconductor substrate 22, silicon substrate 32, and ceramic substrate 50 in photodetection device 10 will be described. Silicon substrate 32 has a thickness smaller than a thickness of compound semiconductor substrate 22. The thickness of compound semiconductor substrate 22 may be 1.25 times to 4 times the thickness of silicon substrate 32. Silicon substrate 32 may have a thickness smaller than a thickness of ceramic substrate 50. In this case, the thickness of silicon substrate 32 may be 0.2 times to 0.55 times the thickness of ceramic substrate 50. The thickness of ceramic substrate 50 may be larger than the thickness of compound semiconductor substrate 22. The thickness of ceramic substrate 50 may be 1.5 times to 4 times the thickness of compound semiconductor substrate 22. When the thicknesses of compound semiconductor substrate 22, silicon substrate 32, and ceramic substrate 50 are respectively referred to as thicknesses T1, T2, and T3, the relationship of the thicknesses T1, T2, and T3 may satisfy T3>T1>T2.

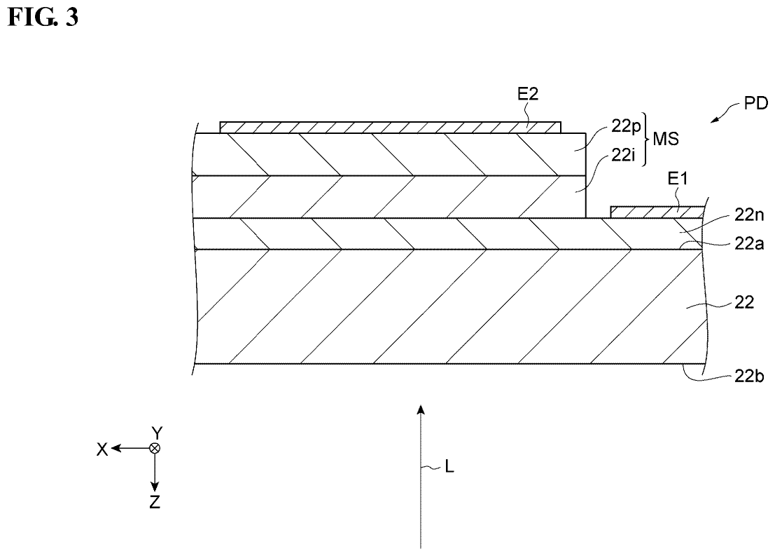

Photodetection device 10 may further include at least one conductor portion 60. The at least one conductor portion 60 may be arranged between third main surface 32a of silicon substrate 32 and first main surface 22a of compound semiconductor substrate 22. The at least one conductor portion 60 may be a plurality of conductor portions 60 arranged in a two dimensional manner on first main surface 22a or third main surface 32a. In this case, the plurality of conductor portions 60 may be spaced apart from each other. Third main surface 32a of silicon substrate 32 and first main surface 22a of compound semiconductor substrate 22 are connected to each other by each of conductor portions 60. Each of conductor portions 60 is a bump including a metal such as indium. Each of conductor portions 60 electrically connects a second electrode E2 (refer to FIG. 3) of each of light-receiving elements PD to an electrode provided on third main surface 32a of silicon substrate 32. Each of conductor portions 60 may have a thickness of 4 μm or less, or 6 μm or less. In the embodiment, a resin portion 70 may be disposed between the plurality of conductor portions 60 adjacent to each other. That is, photodetection device 10 may further include resin portion 70.

Next, the configuration of the plurality of light-receiving elements PD will be described in more detail with reference to FIG. 3. FIG. 3 is an enlarged view of a part of FIG. 2. As shown in FIG. 3, each of the plurality of light-receiving elements PD may include an n-type semiconductor layer 22n, a light-absorbing layer 22i, and a p-type semiconductor layer 22p. N-type semiconductor layer 22n is provided on first main surface 22a of compound semiconductor substrate 22. Light-absorbing layer 22i is provided on n-type semiconductor layer 22n. P-type semiconductor layer 22p is provided on light-absorbing layer 22i. A first electrode El is connected to n-type semiconductor layer 22n. Second electrode E2 is connected to p-type semiconductor layer 22p. Light-absorbing layer 22i and p-type semiconductor layer 22p are included in a mesa MS provided on n-type semiconductor layer 22n. First electrode El is apart from mesa MS.

Each of n-type semiconductor layer 22n and p-type semiconductor layer 22p may include a III-V compound semiconductor. A first barrier layer may be disposed between n-type semiconductor layer 22n and light-absorbing layer 22i. A second barrier layer may be disposed between p-type semiconductor layer 22p and light-absorbing layer 22i. That is, each of the plurality of light-receiving elements PD may include the first barrier layer and the second barrier layer. Each of the first barrier layer and the second barrier layer may include a III-V compound semiconductor.

Light-absorbing layer 22i is sensitive to light L. Light-absorbing layer 22i may include a III-V compound semiconductor. The III-V compound semiconductor may be a ternary compound or a quaternary compound. In this case, the composition of the III-V compound semiconductor can be changed. An example of the ternary compound includes indium gallium arsenide (InGaAs). An example of the quaternary compound includes indium gallium arsenide phosphide (InGaAsP). Light-absorbing layer 22i may have a type-II superlattice structure. In this case, infrared rays having a long wavelength can be detected by each of light-receiving elements PD. The type-II superlattice structure may include a plurality of InGaAs layers and a plurality of GaAsSb layers. The InGaAs layers and the GaAsSb layers are alternately stacked. Light-absorbing layer 22i may be a bulk layer of a III-V compound semiconductor.

Photodetection device 10 has a new structure in which silicon substrate 32 has a thickness smaller than a thickness of compound semiconductor substrate 22.

According to photodetection device 10, it is possible to prevent the generation of cracks that may occur in compound semiconductor substrate 22 and silicon substrate 32 due to a temperature change. For example, when photodetection device 10 is cooled, compound semiconductor substrate 22 and silicon substrate 32 may warp due to a temperature change caused by a difference between the thermal expansion coefficient of the compound semiconductor and the thermal expansion coefficient of silicon. Since the thermal expansion coefficient of the compound semiconductor is larger than the thermal expansion coefficient of silicon, when photodetection device 10 is cooled, for example, an amount of shrinkage of compound semiconductor substrate 22 is larger than an amount of shrinkage of silicon substrate 32. As a result, compound semiconductor substrate 22 and silicon substrate 32 are warped. In photodetection device 10, silicon substrate 32 has a thickness smaller than a thickness of compound semiconductor substrate 22, but the generation of cracks can be prevented.

When adhesive layer 40 including a silicone resin, the generation of cracks can be further prevented.

While the present disclosure has been described in detail with reference to the preferred embodiments, the present disclosure is not limited to the embodiments described above. The constituent elements of the embodiments may be arbitrarily combined.

Hereinafter, an experiment performed for evaluating photodetection device 10 will be described. The experiment described below is not intended to limit the present disclosure.

### First Experiment

In a first experiment, first, a photodetection device as an example of photodetection device 10 shown in FIG. 1 to FIG. 3 was prepared. The photodetection device includes a sensor array including a compound semiconductor substrate and a plurality of light-receiving elements, a readout circuit including a silicon substrate, an adhesive layer, and a ceramic substrate. The compound semiconductor substrate includes a first main surface and a second main surface located opposite to the first main surface. The compound semiconductor substrate includes GaSb as a III-V compound semiconductor. The plurality of light-receiving elements are arranged in a two dimensional manner on the first main surface. The silicon substrate includes a third main surface connected to the first main surface of the compound semiconductor substrate and a fourth main surface located opposite to the third main surface. The adhesive layer is provided on the fourth main surface and includes a silicone resin. The ceramic substrate is connected to the fourth main surface of the silicon substrate with an adhesive layer.

Compound semiconductor had a thickness of 300 μm. Silicon substrate had a thickness of 200 μm. Ceramic substrate had a thickness of 750 μm. That is, in this experiment, the silicon substrate had the thickness smaller than the thickness of the compound semiconductor substrate and the thickness of the ceramic substrate. Then, the prepared photodetection device was cooled from 300 K to 77 K.

### First Experiment Result

In the first experiment, the photodetection device cooled from 300 K to 77 K was observed in order to check whether cracks were generated in the compound semiconductor substrate and the silicon substrate. As a result, it was confirmed that no crack was generated in the compound semiconductor substrate or the silicon substrate.

The embodiments disclosed herein are to be considered in all respects as illustrative and not restrictive. The scope of the present invention is defined by the appended claims rather than the foregoing description, and is intended to include all modifications within the scope and meaning equivalent to the appended claims.

What is claimed is:

1. A photodetection device comprising:
a sensor array including a compound semiconductor substrate including a first main surface and a second main surface located opposite to the first main surface, and a plurality of light-receiving elements arranged in a two dimensional manner on the first main surface;
a readout circuit including a silicon substrate having a third main surface connected to the first main surface of the compound semiconductor substrate and a fourth main surface located opposite to the third main surface;
an adhesive layer provided on the fourth main surface; and
a ceramic substrate connected to the fourth main surface of the silicon substrate with the adhesive layer,
wherein the silicon substrate has a thickness smaller than a thickness of the compound semiconductor substrate.

2. The photodetection device according to claim 1,
wherein the sensor array includes an insulating film provided on the second main surface, and
wherein the insulating film has a thickness of 0.5 μm or less.

3. The photodetection device according to claim 1,
wherein the first main surface has an area of 3 cm² or more.

4. The photodetection device according to claim 1,
wherein the adhesive layer includes a silicone resin.

5. The photodetection device according to claim 1,
wherein the compound semiconductor substrate has a thickness of 250 μm to 350 μm.

6. The photodetection device according to claim 1,
wherein the silicon substrate has a thickness of 150 μm to 250 μm.
